(19) United States
(12) Patent Application Publication
(10) Pub. No.: US 2024/0194695 A1
(43) Pub. Date: Jun. 13, 2024

(54) ELECTRONIC DEVICE

(71) Applicant: InnoLux Corporation, Miao-Li County (TW)

(72) Inventors: Cheng-Yu YANG, Miao-Li County (TW); Yi-Shiuan CHERNG, Miao-Li County (TW); Chih-Hao CHANG, Miao-Li County (TW); Chia-Hao TSAI, Miao-Li County (TW)

(21) Appl. No.: 18/502,025

(22) Filed: Nov. 5, 2023

(30) Foreign Application Priority Data
Dec. 8, 2022 (CN) 202211573177.1

(51) Int. Cl. H01L 27/12

(52) U.S. Cl. CPC H01L 27/1244

(57) ABSTRACT

An electronic device is provided. The electronic device includes a substrate, a data line and a gate line that are disposed on the substrate. The data line extends in a first direction. The electronic device also includes a thin film transistor. The thin film transistor is disposed on the substrate and includes a semiconductor structure. The semiconductor structure includes a channel region, a source region, and a drain region. The gate line overlaps the channel region. The source region is electrically connected to the data line. The source region and the drain region are located on opposite sides of the gate line. The source region includes a first portion extending in a second direction, and an acute angle is formed between the first direction and the second direction.

### CROSS REFERENCE TO RELATED APPLICATIONS

This application claims priority of China Patent Application No. 202211573177.1, filed on Dec. 8, 2022, the entirety of which is incorporated by reference herein.

### BACKGROUND

### Field of the Invention

The present invention relates to an electronic device, and, in particular, to an electronic device in which an acute angle is formed between a portion of the source region and the data line.

### Description of the Related Art

Thanks to technological developments, the use of electronic devices is very common nowadays. In particular, electronic devices with display functions have become an indispensable part of daily life. The demand for increasingly higher resolution in the displays of the electronic devices that are available on the market is constantly increasing. However, the current process limitations have gradually made it difficult to meet the above demand. Therefore, there is still room for improvement over current models.

### BRIEF SUMMARY

An embodiment of the present invention provides an electronic device including a substrate, a data line and a gate line that are disposed on the substrate. The data line extends in a first direction. The electronic device also includes a thin film transistor. The thin film transistor is disposed on the substrate and includes a semiconductor structure. The semiconductor structure includes a channel region, a source region, and a drain region. The gate line overlaps the channel region. The source region is electrically connected to the data line. The source region and the drain region are located on opposite sides of the gate line. The source region includes a first portion extending in a second direction, and an acute angle is formed between the first direction and the second direction.

An embodiment of the present invention provides an electronic device including a substrate, a data line and a gate line that are disposed on the substrate. The data line extends in a first direction. The electronic device also includes a thin film transistor. The thin film transistor is disposed on the substrate and includes a semiconductor structure. the semiconductor structure includes a channel region, a source region and a drain region. The gate line overlaps the channel region, the channel region at least partially overlaps the data line, and the source region is electrically connected to the data line. The source region and the drain region are located on opposite sides of the gate line. The drain region includes a first portion extending along a second direction, and an acute angle is formed between the first direction and the second direction.

### BRIEF DESCRIPTION OF THE DRAWINGS

The present invention can be more fully understood by reading the subsequent detailed description and examples with references made to the accompanying drawings, wherein:

FIG. 1 shows a partial plan view of an electronic device in accordance with some embodiments of the present disclosure.

FIG. 2 shows a partially enlarged view of a semiconductor structure in accordance with some embodiments of the present disclosure.

FIG. 3 shows a partial plan view of the electronic device in accordance with some embodiments of the present disclosure.

FIG. 4 shows a partial plan view of the electronic device in accordance with some embodiments of the present disclosure.

FIG. 5 shows a partially enlarged view of the electronic device in accordance with some embodiments of the present disclosure.

FIG. 6 shows a partial plan view of the electronic device in accordance with some embodiments of the present disclosure.

FIG. 7 shows a partial plan view of the electronic device in accordance with some embodiments of the present disclosure.

FIG. 8 shows a partial plan view of the electronic device in accordance with some embodiments of the present disclosure.

FIG. 9 shows a partial plan view of the electronic device in accordance with some embodiments of the present disclosure.

### DETAILED DESCRIPTION

The present disclosure may be understood by referring to the following description and the appended drawings. It should be noted that, in order to make it easy for the reader to understand and to make the drawings concise, the drawings in the present disclosure may illustrate a part of the light-emitting unit, and specific elements in the drawings are not drawn based on the actual scale. In addition, the number and the size of each component in the drawings merely serves as an example, and are not intended to limit the scope of the present disclosure. Furthermore, similar and/or corresponding numerals may be used in different embodiments for describing some embodiments simply and clearly, but not represent any relationship between different embodiment and/or structures discussed below.

Certain terms may be used throughout the present disclosure and the appended claims to refer to particular elements. Those skilled in the art will understand that electronic device manufacturers may refer to the same components by different names. The present specification is not intended to distinguish between components that have the same function but different names. In the following specification and claims, the words “including”, “comprising”, “having” and the like are open words, so they should be interpreted as meaning “including but not limited to . . . ”. Therefore, when terms “including”, “comprising”, and/or “having” are used in the description of the disclosure, the presence of corresponding features, regions, steps, operations and/or components is specified without excluding the presence of one or more other features, regions, steps, operations and/or components.

In addition, in this specification, relative expressions may be used. For example, “lower”, “bottom”, “higher” or “top” are used to describe the position of one element relative to another. It should be noted that if a device is flipped upside down, an element that is “lower” will become an element that is “higher”.

When a corresponding component (such as a film layer or region) is referred to as “on another component”, it may be directly on another component, or there may be other components in between. On the other hand, when a component is referred “directly on another component”, there is no component between the former two. In addition, when a component is referred “on another component”, the two components have an up-down relationship in the top view, and this component can be above or below the other component, and this up-down relationship depends on the orientation of the device.

It should be understood that, although the terms “first”, “second” etc. may be used herein to describe various elements, layers and/or portions, and these elements, layers, and/or portions should not be limited by these terms. These terms are only used to distinguish one element, layer, or portion. Thus, a first element, layer or portion discussed below could be termed a second element, layer or portion without departing from the teachings of some embodiments of the present disclosure. In addition, for the sake of brevity, terms such as “first” and “second” may not be used in the description to distinguish different elements. As long as it does not depart from the scope defined by the appended claims, the first element and/or the second element described in the appended claims can be interpreted as any element that meets the description in the specification.

In the present disclosure, the thickness, length, and width can be measured by using an optical microscope, and the thickness can be measured by the cross-sectional image in the electron microscope, but it is not limited thereto. In addition, a certain error may be present in a comparison with any two values or directions. The terms “about,” “equal to,” “equivalent,” “the same,” “essentially” or “substantially” are generally interpreted as within 10% of a given value or range, or as interpreted as within 5%, 3%, 2%, 1%, or 0.5% of a given value or range. In addition, the term “electrically connected” may be used below. It should be understood that if the present disclosure recites “the first element is electrically connected to the second element,” it may be interpreted as that the first element and the second element are electrically connected to each other and may be synchronously controlled by a single operation, which may include the case “there may be other elements between the first element and the second element to electrically connect the former two,” or include “the first element and the second element are directly electrically connected without other elements.” When it is mentioned in the present disclosure that the first element is “directly electrically connected” to the second element, it may be referred to as that “the first element and the second element are directly electrically connected without other elements.” In addition, the term “electrically insulated” may be used below. It should be understood that if the present disclosure recites “the first element and the second element are electrically insulated,” it may be interpreted as that the first element and the second element are electrically separated without being connected to each other, nor synchronously controlled by a single operation.

It should be noted that the technical solutions provided by different embodiments below may be interchangeable, combined or mixed to form another embodiment without departing from the spirit of the present disclosure.

Unless defined otherwise, all terms (including technical and scientific terms) used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined in the present disclosure.

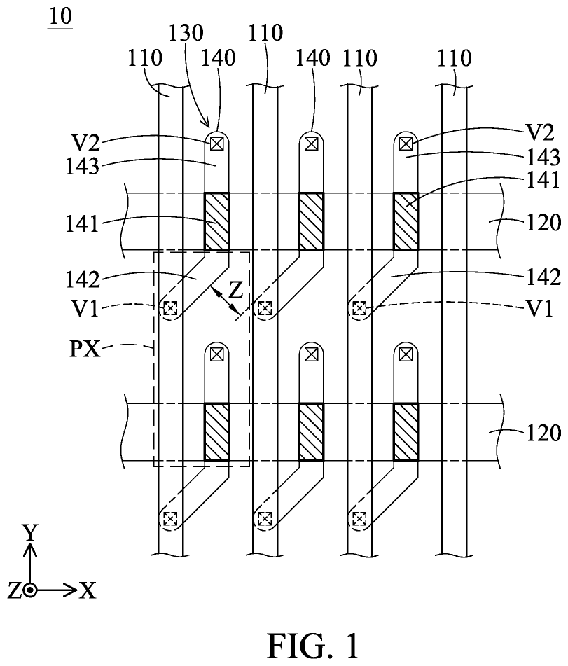

FIG. 1 shows a partial plan view of an electronic device 10 in accordance with some embodiments of the present disclosure. In some embodiments, the electronic device 10 can be used in buildings or vehicles to adjust light, but the present disclosure is not limited thereto. In some embodiments, the electronic device 10 may be used in accompany with another electronic device (not shown). For example, the electronic device may include a display device, a backlight device, an antenna device, a sensing device or a splicing device, but the present disclosure is not limited thereto. The electronic device may be a bendable or flexible electronic device. The display device may be a non-self-luminous display device or a self-luminous display device. The antenna device may be a liquid-crystal type antenna device or a non-liquid-crystal type antenna device. The sensing device may be a sensing device for sensing capacitance, light, thermal energy or ultrasonic waves, but the present disclosure is not limited thereto. In some embodiments, the electronic device includes a flexible panel, and the flexible panel includes electronic components, and the electronic components may include passive components and active components, such as capacitors, resistors, inductors, diodes, transistors, and the like. In some embodiments, the diodes may include light-emitting diodes or photodiodes. The light-emitting diodes may, for example, include organic light-emitting diodes (OLEDs), mini LEDs, micro LEDs or quantum dot LEDs, but the present disclosure is not limited thereto. The splicing device may be, for example, a display splicing device or an antenna splicing device, but the present disclosure is not limited thereto. It should be noted that the electronic device may be any combination of the above-mentioned devices, but the present disclosure is not limited thereto. In addition, the shape of the electronic device 10 may be rectangular, circular, polygonal, shapes with curved edges or other suitable shapes. The electronic device may have peripheral systems such as drive systems, control systems, and light source systems to support display devices, antenna devices, wearable devices (such as including augmented reality or virtual reality), vehicle-mounted devices (such as including car windshields), or splicing devices. It should be understood that the content of the present disclosure will be discussed with respect to the partial structure of the electronic device 10 in the following paragraphs, and those skilled in the art should understand that the electronic device 10 may also include other structures to perform expected functions.

As shown in FIG. 1, the electronic device 10 may include a substrate (not shown) and data lines 110 and gate lines 120 that are disposed on the substrate. In some embodiments, the substrate may include flexible or inflexible substrates, or a combination thereof, but the present disclosure is not limited thereto. The material of the substrate may include glass, quartz, ceramics, sapphire, rubber, polymer materials such as polyimide (PI), polyethylene naphthalate (PEN), polycarbonate (PC), polyurethane, polydimethylenesiloxane or/and polyethylene terephthalate (PET), at least one of the above materials, a mixture of the above materials, other suitable materials or a combination thereof, but the present disclosure is not limited thereto. In some embodiments, the gate lines 120 have an extension direction (for example, along the X-axis), and the data lines 110 have another extension direction. In some embodiments, the extending direction of the gate lines 120 is different from the extending direction of the data lines 110. In some other embodiments, the extending direction (for example, along the Y-axis) of the data lines 110 is perpendicular to the extending direction of the gate lines 120, but the present disclosure is not limited thereto. It should be understood that the above-mentioned axes serve as an example for ease of understanding but not for limitation. In some embodiments, the data lines 110 and the gate lines 120 may each extend along any two directions that are substantially perpendicular to each other.

In some embodiments, the area enclosed by two adjacent data lines 110 and two adjacent gate lines 120 (for example, the area enclosed by the center lines of the signal lines or the edge area enclosed by the same side of the signal lines) may be defined as a sub-pixel PX. In some embodiments, a “pixel” may be a stack structure including all related layers, related components or related parts configured to emit light with certain brightness and color. For a liquid crystal display, a pixel may include a relevant part of a liquid crystal layer, a relevant part of a polarizer, a relevant part of a backlight, and relevant substrates, driving circuits, and color filters. For self-emitting displays (such as inorganic light-emitting diode displays (LEDs) and organic light-emitting diode displays (OLEDs), pixels may include relevant self-emitting sources, relevant light conversion layers, relevant parts of polarizers, relevant substrates, and relevant driving circuits.

In addition, the electronic device 10 also includes thin film transistors 130. In some embodiments, the thin film transistors 130 are disposed on the substrate and each include a semiconductor structure 140. For example, the semiconductor structure 140 may include polysilicon or indium gallium zinc oxide (IGZO), or be made of the aforementioned materials. The semiconductor structure 140 includes a channel region 141, a source region 142 and a drain region 143, wherein the channel region 141 may be located between the source region 142 and the drain region 143. In some embodiments, the channel region 141 may be a portion where the semiconductor structure 140 overlaps the gate line 120, and the source region 142 and the drain region 143 are located on opposite sides of the gate line 120. In some embodiments, the source region 142 is electrically connected to the data line 110 and does not overlap the gate line 120. The source region 142 may have a bent structure. As a result, the distance between adjacent semiconductor structures 140 may be shortened without decreasing the yield, so as to improve the resolution of the electronic device 10.

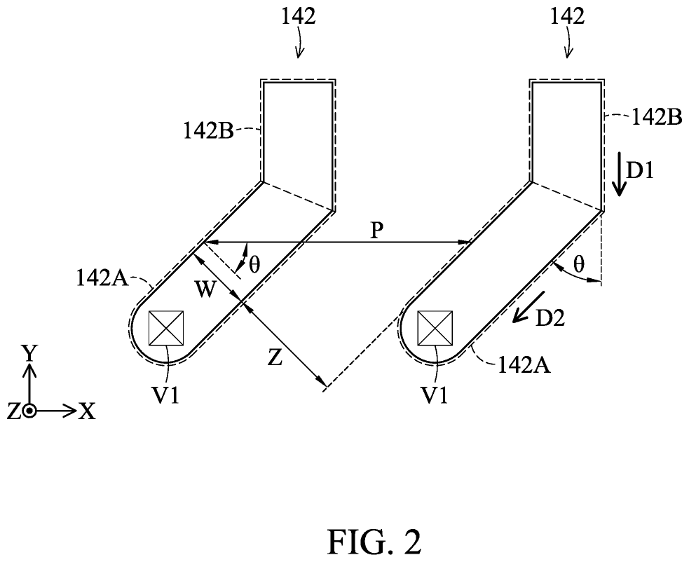

In some embodiments, the thin film transistor 130 further includes a gate electrode, a source electrode and a drain electrode, and the gate electrode may be a part of the gate line and the part overlaps the semiconductor structure 140. In other words, the overlapping portion of the gate line 120 and the channel region 141 can be regarded as the gate electrode. The source electrode is, for example, a part of the data line 110, and is electrically connected to the source region 142 through the holes V1. The drain electrode (not shown) may at least partially overlap the drain region 143 and be electrically connected to the drain region 143 through the holes V2. For example, the drain electrode may be formed of the same layer of metal as the data line 110, but the present disclosure is not limited thereto. The detailed structure of the source region 142 will be further described below with reference to FIG. 2. In some embodiments, the source electrode may be electrically connected to the transparent conductive layer (for example, the pixel electrode), but the present disclosure is not limited thereto. It should be understood that, for the sake of brevity, the following embodiments will not discuss the structures of the holes V1 and V2 in detail. It should be understood by those skilled in the art that the holes V1 and the holes V2 may be arranged in the above manner in all embodiments of the present application.

FIG. 2 shows a partially enlarged view of the semiconductor structure 140 in accordance with some embodiments of the present disclosure. As shown in FIG. 2, the source region 142 includes a first portion 142A and a second portion 142B. In some embodiments, the second portion 142B may be located between the first portion 142A and the channel region 141 (for example, referring to FIG. 1). The second portion 142B extends along a first direction D1 (that is substantially parallel to the direction in which the data line 110 extends), and the first portion 142A extends along a second direction D2. There is an angle θ between the first direction D1 and the second direction D2, and the angle θ may be an acute angle (in other words, the angle θ can be greater than 0° and less than 90°, that is 0°<θ<90°).

In some embodiments, the pitch P between adjacent semiconductor structures 140 (such as source regions 142) may be defined as the distance between the same points on the same side of the semiconductor structures 140 along a horizontal direction (such as the X-axis). The distance Z is the shortest distance between adjacent semiconductor structures 140. The semiconductor structure 140 (for example, the first portion 142A) may have a width W. In some embodiments, the pitch P is, for example, greater than 0 μm and less than 20 μm (0 μm<P<20 μm), the distance Z is, for example, greater than 0 μm and less than 15 μm (0 μm<Z<15 μm), and the width W is, for example, greater than 0 μm and less than 15 μm (0 μm<W<15 μm), but the present disclosure is not limited thereto. The angle θ may satisfy the following relationship:

$$0 ° < θ \leq {cos}^{- 1} ( \frac{W + Z}{P} ) .$$

By virtue of the above design, the distance between adjacent semiconductor structures 140 may be reduced, so as to increase the arrangement density of the thin film transistors 130, thereby improving the resolution of the electronic device 10. In addition, the shape (for example, rectangular in a plan view) of the channel region 141 on the gate line 120 may also be maintained to reduce the risk of affecting its electrical characteristics. In some embodiments, the drain region 143 may be disposed at the center between the adjacent data lines 110, so as to reduce the risk of short circuit occurred between the drain region 143 and the data lines 110.

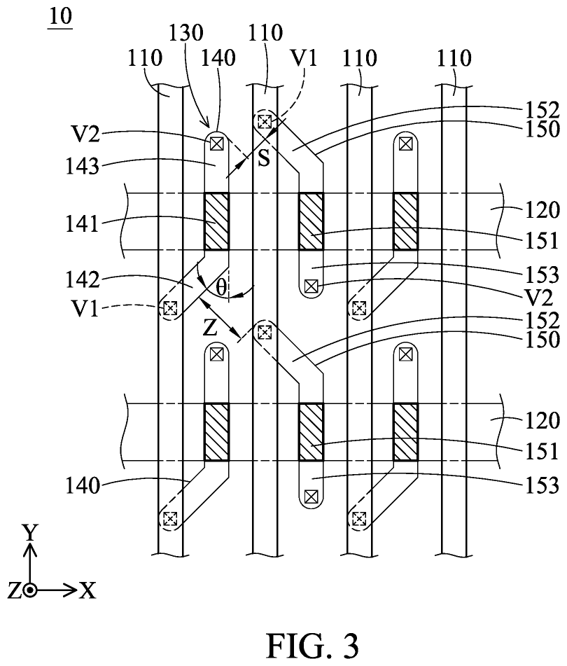

FIG. 3 shows a partial plan view of the electronic device 10 in accordance with some embodiments of the present disclosure. It should be understood that the electronic device 10 in this embodiment may include the same or similar structures as the electronic device 10 shown in FIG. 1. These structures will be denoted by the same or similar numerals, and will not be discussed in detail as follows. For example, as shown in FIG. 3, the electronic device 10 may include a substrate (not shown) and data lines 110 and gate lines 120 that are disposed on the substrate. In addition, the electronic device 10 also includes thin film transistors 130 that are disposed on the substrate and include semiconductor structures 140 and other semiconductor structures 150. The difference between the present embodiment and the structure shown in FIG. 1 is that the semiconductor structures 150 and the semiconductor structures 140 may be arranged in a staggered manner.

In some embodiments, the semiconductor structures 150 each include a channel region 151, a source region 152 and a drain region 153, wherein the channel region 151 may be located between the source region 152 and the drain region 153. In some embodiments, the channel region 151 may be a portion of the semiconductor structure 150 overlapping the gate line 120, while the source region 152 and the drain region 153 are located on opposite sides of the gate line 120. In some embodiments, the source region 152 is electrically connected to the data line 110 and does not overlap the gate line 120. The source region 152 may have a bent structure. The source region 142 of the semiconductor structure 140 and the source region 152 of the semiconductor structure 150 may be located on opposite sides of the gate line 120. As a result, the distance S and the distance Z between the adjacent semiconductor structures 140 and 150 may be shortened without decreasing the yield. For example, the distance S may be the shortest distance between the upper left semiconductor structure 140 in FIG. 3 and the upper right semiconductor structure 150 in FIG. 3. For example, the distance S is the shortest distance between adjacent semiconductor structures along the extending direction of the gate line. The distance Z may be the shortest distance between the upper left semiconductor structure 140 in FIG. 3 and the lower right semiconductor structure 150 in FIG. 3, wherein the angle θ respectively satisfies the following relationships:

$$0 ° < θ \leq {cos}^{- 1} ( \frac{W + S}{P} ) ; and 0 ° < θ \leq {cos}^{- 1} ( \frac{W + Z}{P} ) .$$

In some embodiments, a change of the angle θ may affect both the distance S and the distance Z. For example, when the angle θ increases, the distance Z may increase and the distance S may decrease, and vice versa. In some embodiments, the distance Z and/or the distance S may be, for example, greater than or equal to 0.1 μm. It should be understood that the above-mentioned orientations of the distance S and the distance Z are merely examples, and those skilled in the art may derive the distance between any two adjacent semiconductor structures according to the content of the present disclosure. Similarly, by virtue of the above design, the arrangement density of the thin film transistors 130 may be increased, thereby improving the resolution of the electronic device 10. In addition, the shapes (for example, rectangular in a plan view) of the channel region 141 and/or the channel region 151 located on the gate line 120 may also be maintained, thereby reducing electrical differences caused by process variations and improving the electrical uniformity of the entire thin film transistor. The drain region 143 and/or the drain region 153 may be kept at the center between the adjacent data lines 110, thereby reducing the risk of the drain region 143 and/or the drain region 153 being short-circuited with the data line 110.

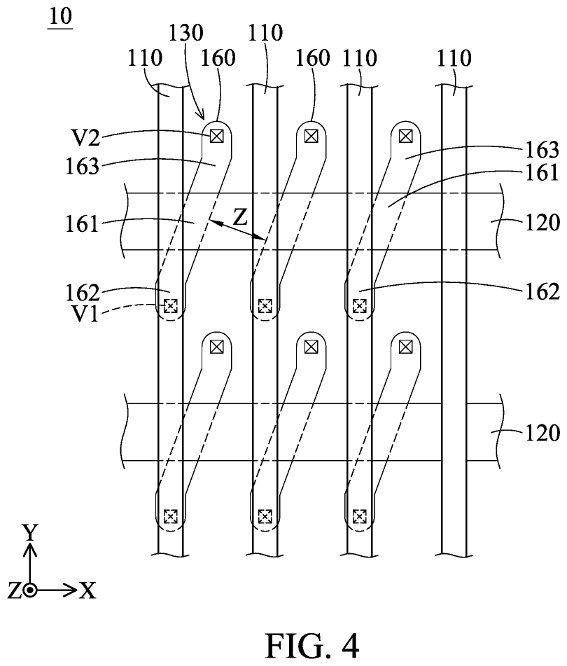

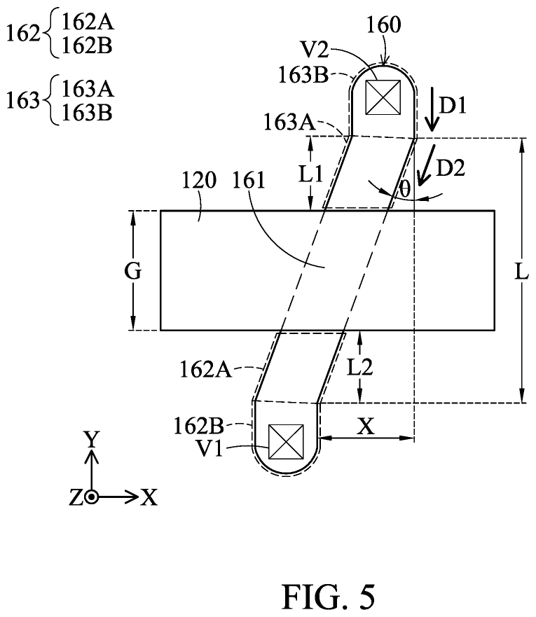

FIG. 4 shows a partial plan view of the electronic device 10 in accordance with some embodiments of the present disclosure. It should be understood that the electronic device 10 in the present embodiment may include the same or similar structures as the electronic device 10 shown in FIG. 1. These structures will be denoted by the same or similar numerals, and will not be discussed in detail as follows. For example, as shown in FIG. 4, the electronic device 10 may include a substrate (not shown) and data lines 110 and gate lines 120 that are disposed on the substrate. In addition, the electronic device 10 also includes thin film transistors 130 that are disposed on the substrate and include semiconductor structures 160. The difference between this embodiment and the structure shown in FIG. 1 is that the semiconductor structures 160 may each include a channel region 161, a source region 162 and a drain region 163, wherein the channel region 161 may be located between the source region 162 and the drain region 163. In some embodiments, the channel region 161 may be a portion where the semiconductor structure 150 overlaps the gate line 120. The channel region 161 has an extending direction. For example, the extending direction of the channel region 161 is not perpendicular to the extending direction of the gate lines 120. The source region 162 and the drain region 163 are located on opposite sides of the gate line 120. In some embodiments, the source region 162 is electrically connected to the data line 110 and does not overlap the gate line 120, and both the source region 162 and the drain region 163 have a bent structure. In some embodiments, the source region 162 and the data line 110 may partially overlap (for example, viewed in a plan view (along the Z axis)). In some embodiments, the distance Z may be the shortest distance between adjacent semiconductor structures 160. As a result, the distance between adjacent semiconductor structures 160 may be shortened to increase the arrangement density of the thin film transistors 130, thereby improving the resolution of the electronic device 10 without decreasing the yield. The detailed structure of the semiconductor structure 160 will be further described below with reference to FIG. 5.

FIG. 5 shows a partially enlarged view of the electronic device 10 in accordance with some embodiments of the present disclosure. As shown in FIG. 5, the channel region 161 of the semiconductor structure 160 is non-rectangular (such as a parallelogram) in a plan view, and extends, for example, along the second direction D2. In some embodiments, the source region 162 has a first portion 162A and a second portion 162B. In some embodiments, the first portion 162A may be located between the second portion 162B and the channel region 161. The first portion 162A extends along the second direction D2, and the second portion 162B extends along the first direction D1 (that is substantially parallel to the Y axis, also the direction in which the data line 110 extends). There is an angle θ between the first direction D1 and the second direction D2, and the angle θ may be an acute angle (in other words, the angle θ may be greater than 0° and less than 90°, that is 0°<θ<90°). In some embodiments, the first portion 162A of the source region 162 has a length L2, wherein the length L2 may be measured, for example, along a direction that is substantially parallel to the Y-axis. In some other embodiments, the first portion 162A of the source region 162 extending along the second direction D2 may be omitted, and the second portion 162B of the source region 162 extending along the first direction D1 remains.

In addition, the drain region 163 also has a first portion 163A and a second portion 163B. In some embodiments, the first portion 163A may be located between the second portion 163B and the channel region 161. The first portion 163A extends along the second direction D2, and the second portion 163B extends along the first direction D1 (which is substantially parallel to the Y-axis, and the direction in which the data line 110 extends). In some other embodiments, the first portion 163A of the drain region 163 extending along the second direction D2 may be omitted, and the second portion 163B of the drain region 163 extending along the first direction D1 remains. In some embodiments, the first portion 163A of the drain region 163 has a length L1, wherein the length L1 may be measured, for example, along a direction that is substantially parallel to the Y-axis. The length L of the inclined portion (including the channel region 161, the first portion 162A of the source region 162, and the first portion 163A of the drain region 163) of the semiconductor structure 160 may be the sum of the length L1, the length L2, and the width G of the gate line 120, wherein the length L may be measured, for example, along a direction that is substantially parallel to the Y-axis. In some embodiments, the length L of the inclined portion is greater than or equal to the width G of the gate line 120 in the first direction D1. In addition, the distance X may be defined as the lateral distance between the source region 162 and the drain region 163, where the distance X may be measured, for example, along a direction that is substantially parallel to the X axis, and measured on the same side of the source region 162 and the drain region 163 (for example, measured from the right side of the second portion 162B of the source region 162 to the right side of the second portion 163B of the drain region 163). In some embodiments, the width G is, for example, greater than 0 μm, and the distance X is, for example, greater than 0 μm and less than 10 μm.

In some embodiments, the minimum value of length L1 and length L2 may be greater than or equal to 0, which may increase the arrangement density of thin film transistors and/or reduce the risk of electrical variation. As mentioned above, the angle θ satisfies the following relationship:

$$0 ° < θ \leq {tan}^{- 1} ( \frac{X}{L} ) .$$

It should be noted that the present disclosure is not limited thereto. All of the above-mentioned semiconductor structures fall within the scope of the present disclosure. In some other embodiments, at least a portion of the second portion 162B of the source region 162 and/or at least a portion of the second portion 163B of the drain region 163 may overlap the gate line 120. By virtue of the above design, the arrangement density of the thin film transistors 130 may be increased, thereby improving the resolution of the electronic device 10. In addition, the drain region 163 may be maintained at the center between adjacent data lines 110, thereby reducing the risk of short circuit occurred between the drain region 163 and the data lines 110.

In this embodiment, the pitch P between adjacent semiconductor structures 160 (such as the source regions 162) may be defined as the distance along a horizontal direction (such as the X-axis) between the same points on the same side of the semiconductor structures 160. The distance Z is the shortest distance between adjacent semiconductor structures 160. The semiconductor structures 160 (for example, the first portions 162A) may have a width W. In some embodiments, the pitch P is, for example, greater than 0 μm and less than 20 μm (0 μm<P<20 μm), the distance Z is, for example, greater than 0 μm and less than 15 μm (0 μm<Z<15 μm), and the width W is, for example, greater than 0 μm and less than 15 μm (0 μm<W<15 μm), but the present disclosure is not limited thereto. The angle θ may satisfy the following relationship:

$$0 ° < θ \leq {cos}^{- 1} ( \frac{W + Z}{P} ) .$$

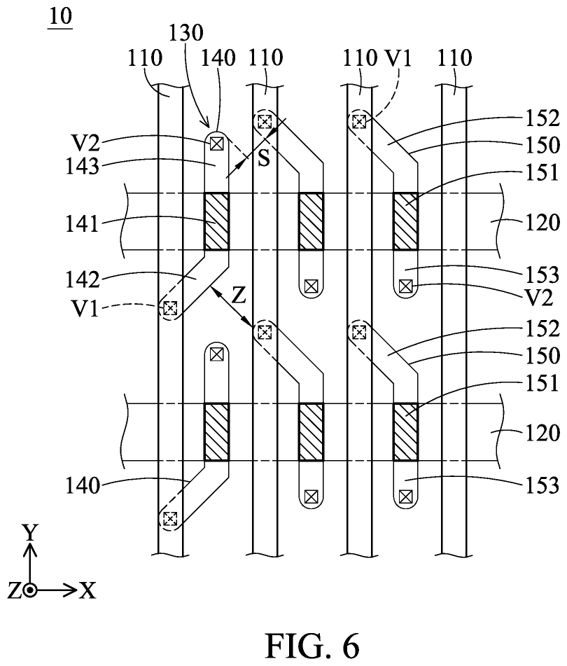

FIG. 6 shows a partial plan view of the electronic device 10 in accordance with some embodiments of the present disclosure. It should be understood that the electronic device 10 in this embodiment may include the same or similar structures as the electronic device 10 shown in FIG. 1. These structures will be denoted by the same or similar numerals, and will not be discussed in detail as follows. For example, as shown in FIG. 6, the electronic device 10 may include a substrate (not shown) and data lines 110 and gate lines 120 that are disposed on the substrate. In addition, the electronic device 10 also includes thin film transistors 130 that are disposed on the substrate and include semiconductor structures 140 and other semiconductor structures 150. In the present embodiment, the semiconductor structures 140 and the semiconductor structures 150 are respectively arranged along the Y-axis direction, and in the X-direction, for example, one semiconductor structure 140 and two semiconductor structures 150 are alternately arranged. More specifically, the two semiconductor structures 150 may be arranged between the two semiconductor structures 140 in the horizontal direction (for example, the X axis), but the present disclosure is not limited thereto. In some embodiments, in the horizontal direction (such as the X-axis), the semiconductor structures 140 and the semiconductor structures 150 can be arranged alternately in any number. All possible configurations of the semiconductor structures 140 and the semiconductor structures 150 will not be listed one-by-one below, and these configurations are included within the scope of the present disclosure.

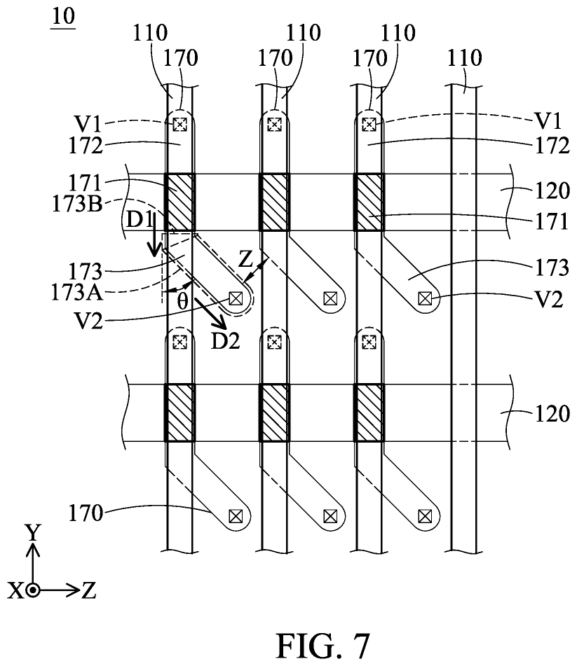

FIG. 7 shows a partial plan view of an electronic device 10 according to some embodiments of the present disclosure. It should be understood that the electronic device 10 in this embodiment may include the same or similar structures as the electronic device 10 shown in FIG. 1. These structures will be denoted by the same or similar numerals, and will not be discussed in detail as follows. For example, as shown in FIG. 7, the electronic device 10 may include a substrate (not shown) and data lines 110 and gate lines 120 that are disposed on the substrate. In addition, the electronic device 10 also includes thin film transistors 130 that are disposed on the substrate and include semiconductor structures 170.

More specifically, the semiconductor structures 170 each include a channel region 171, a source region 172 and a drain region 173, wherein the channel region 171 may be located between the source region 172 and the drain region 173, and at least partially overlap the data line 110. In some embodiments, the channel region 171 may be a portion where the semiconductor structure 170 overlaps the gate line 120, while the source region 172 and the drain region 173 are located on opposite sides of the gate line 120. In some embodiments, the source region 172 is electrically connected to the data line 110 and does not overlap the gate line 120. The drain region 173 may have a bent structure. For example, the drain region 173 has a first portion 173A and a second portion 173B, the first portion 173A extends along the second direction D2, and the second portion 173B extends along the first direction D1 (which is substantially parallel to the Y axis, that is, the direction in which the data lines 110 extend). The second portion 173B may be located between the first portion and the channel region 171. As a result, the distance between adjacent semiconductor structures 170 may be shortened, thereby increasing the arrangement density of thin film transistors. In some embodiments, the drain region 173 may at least partially overlap the data line 110.

In some embodiments, there is an angle θ between the second direction D2 (that is, the direction in which the first portion 173A extends) and the first direction D1 (that is, the direction in which the second portion 173B extends), and the angle θ may be an acute angle (in other words, the angle θ may be larger than 0° and smaller than 90°, that is 0°<θ<90°). The specific range of the angle θ may be determined in the same manner as in the above-mentioned embodiments of the present disclosure (for example, referring to FIG. 2), which will not be repeated hereafter. In this way, the distance between adjacent semiconductor structures 170 may be shortened without decreasing the yield, thereby improving the display resolution of the electronic device 10. In some embodiments, the drain region 173 may at least partially overlap the data line 110.

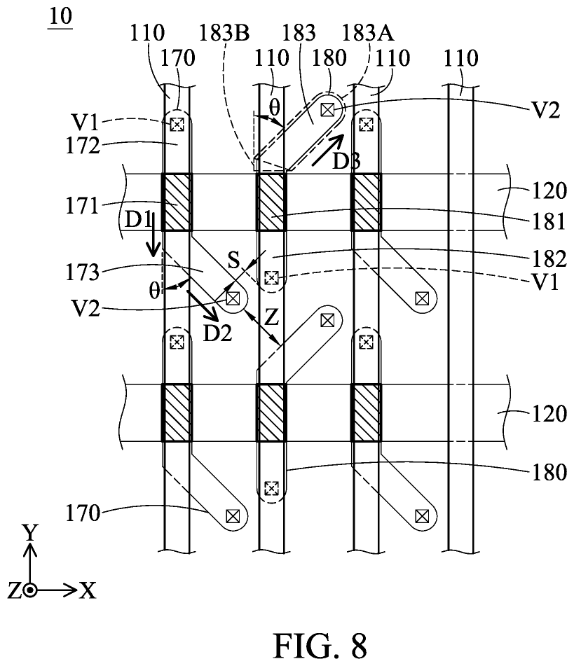

FIG. 8 shows a partial plan view of the electronic device 10 in accordance with some embodiments of the present disclosure. It should be understood that the electronic device 10 in this embodiment may include the same or similar structures as the electronic device 10 shown in FIG. 1. These structures will be denoted by the same or similar numerals, and will not be discussed in detail as follows. For example, as shown in FIG. 8, the electronic device 10 may include a substrate (not shown) and data lines 110 and gate lines 120 that are disposed on the substrate. In addition, the electronic device 10 also includes thin film transistors 130 that are disposed on the substrate and include semiconductor structures 170 and other semiconductor structures 180. The semiconductor structures 180 may be disposed as a mirror image with respect to the semiconductor structures 170.

In the present embodiment, the semiconductor structures 180 each include a channel region 181, a source region 182 and a drain region 183, wherein the channel region 181 may be located between the source region 182 and the drain region 183, and at least partially overlap the data line 110. In some embodiments, the channel region 181 may be a portion where the semiconductor structure 180 overlaps the gate line 120, and the source region 182 and the drain region 183 are located on opposite sides of the gate line 120. In some embodiments, the source region 182 is electrically connected to the data line 110 and does not overlap the gate line 120. The drain region 183 may have a bent structure. For example, the drain region 183 has a first portion 183A and a second portion 183B, the first portion 183A extends along a third direction D3, and the second portion 183B extends along the first direction D1 (which is substantially parallel to the Y-axis, and the direction in which the data lines 110 extend). The second portion 183B may be located between the first portion 183A and the channel region 181. In some embodiments, the third direction D3 may be perpendicular to the second direction D2. As a result, the distance between adjacent semiconductor structures 180 may be shortened, thereby increasing the arrangement density of thin film transistors. In some embodiments, the drain region 183 may at least partially overlap the data line 110.

In some embodiments, there is an angle θ between the third direction D3 (that is, the direction in which the first portion 183A extends) and the first direction D1 (that is, the direction in which the second portion 183B extends), and the angle θ may be an acute angle (in other words, the angle θ may be larger than 0° and smaller than 90°, namely 0°<θ<90°). The specific range of the angle θ may be determined in the same way as the above-mentioned embodiments of the present disclosure (for example, referring to FIG. 3), which will not be repeated hereafter. In this way, the distance between adjacent semiconductor structures 170 and semiconductor structures 180 may be shortened without decreasing the yield, thereby improving the display resolution of the electronic device 10. In some embodiments, the drain region 183 may at least partially overlap the data line 110.

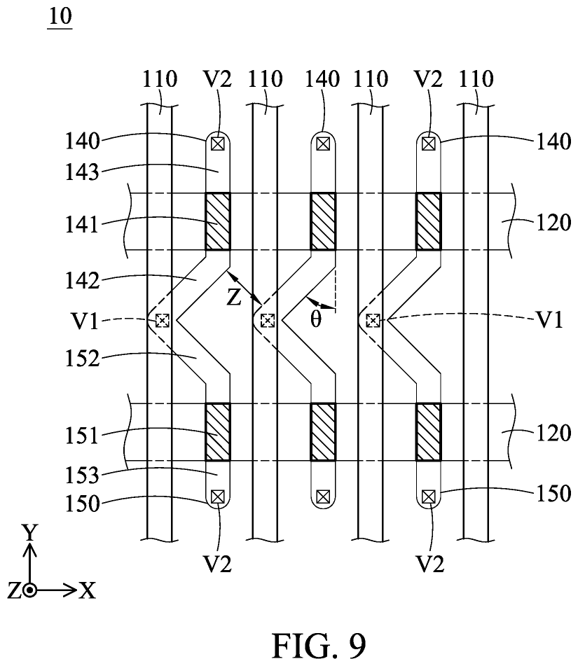

FIG. 9 shows a partial plan view of an electronic device 10 according to some embodiments of the present disclosure. It should be understood that the electronic device 10 in this embodiment may include the same or similar structures as the electronic device 10 shown in FIG. 1. These structures will be denoted by the same or similar numerals, and will not be discussed in detail as follows. For example, as shown in FIG. 9, the electronic device 10 may include a substrate (not shown) and data lines 110 and gate lines 120 that are disposed on the substrate. In addition, the electronic device 10 also includes thin film transistors 130 that are disposed on the substrate and include semiconductor structures 140 and other semiconductor structures 150. The semiconductor structures 150 may be arranged as a mirror image with respect to the semiconductor structures 140.

In some embodiments, the source region 142 of the semiconductor structures 140 and the source region 152 of the semiconductor structures 150 may have a bent structure and overlap the data line 110. For example, the source region 142 of the semiconductor structures 140 may intersect the source region 152 of the semiconductor structures 150, but the present disclosure is not limited thereto. In some other embodiments, the semiconductor structures 140 and the semiconductor structures 150 may share a source. In this way, the distance between adjacent semiconductor structures 140 and/or semiconductor structures 150 may be shortened to increase the arrangement density of the thin film transistors. In addition, the drain region 143 of the semiconductor structures 140 and the drain region 153 of the semiconductor structures 150 may be located at the center of the adjacent data lines 110 (that is, equidistant from the adjacent data lines 110), which may reduce the risk of short circuit occurred between the drain region 143 of the semiconductor structure 140 (and the drain region 153 of the semiconductor structure 150) and the data line 110.

It should be understood that although the above-mentioned embodiment merely shows a part of the configuration of the electronic device 10, those skilled in the art should be able to arrange other optical layers and/or optical elements in the structure discussed in the present disclosure, so as to enhance the display and/or touch effect according to the teaching of the present disclosure. These configurations derived from the present disclosure are also included in the scope of the present disclosure. In addition, the present disclosure also provides several different semiconductor structures, those skilled in the art should be able to combine/arrange these semiconductor structures arbitrarily without violating the teachings of the present disclosure, and these arrangements and combinations are all included in within the scope of this disclosure.

As set forth above, the embodiments of the present disclosure provide an electronic device in which a part of the source region and/or the drain region is disposed to have an acute angle relative to the data line. By virtue of the above features, the arrangement density of the thin film transistors may be increased, thereby improving the resolution of the electronic device. In addition, in some embodiments, the shape (for example, rectangular or other regular shape in a plan view) of the channel region on the gate line may be maintained to reduce the risk of affecting its electrical characteristics. In some embodiments, the drain region may be disposed at the center between adjacent data lines, thereby reducing the risk of short circuit occurred between the drain region and the data lines.

While the embodiments and the advantages of the present disclosure have been described above, it should be understood that those skilled in the art may make various changes, substitutions, and alterations to the present disclosure without departing from the spirit and scope of the present disclosure. It should be noted that different embodiments may be arbitrarily combined as other embodiments as long as the combination conforms to the spirit of the present disclosure. In addition, the scope of the present disclosure is not limited to the processes, machines, manufacture, composition, devices, methods and steps in the specific embodiments described in the specification. Those skilled in the art may understand existing or developing processes, machines, manufacture, compositions, devices, methods and steps from some embodiments of the present disclosure. Therefore, the scope of the present disclosure includes the aforementioned processes, machines, manufacture, composition, devices, methods, and steps. Furthermore, each of the appended claims constructs an individual embodiment, and the scope of the present disclosure also includes every combination of the appended claims and embodiments.

What is claimed is:

1. An electronic device, comprising:
a substrate;
a data line and a gate line disposed on the substrate, wherein the data line extends along a first direction; and
a thin film transistor arranged on the substrate and comprising a semiconductor structure, wherein the semiconductor structure comprises a channel region, a source region and a drain region, wherein the gate line overlaps the channel region, the source region is electrically connected to the data line, the source region and the drain region are located on opposite sides of the gate line,
wherein the source region comprises a first portion extending along a second direction, and an acute angle is formed between the first direction and the second direction.

2. The electronic device as claimed in claim 1, comprising a plurality of thin film transistors, and the thin film transistors are disposed on the substrate and each comprise a semiconductor structure, and there is a pitch (P) and a shortest distance (Z) between two adjacent semiconductor structures, the semiconductor structures have a width (W), and the acute angle (θ) satisfies the following relationship:
$$0 ° < θ \leq {cos}^{- 1} ( \frac{W + Z}{P} ) .$$

3. The electronic device as claimed in claim 2, wherein the pitch is greater than 0 μm and less than 20 μm.

4. The electronic device as claimed in claim 2, wherein the shortest distance is greater than 0 μm and less than 15 μm.

5. The electronic device as claimed in claim 2, wherein the width is greater than 0 μm and less than 15 μm.

6. The electronic device as claimed in claim 2, wherein the source region comprises a second portion extending along the first direction, and the second portion is located between the first portion and the channel region.

7. The electronic device as claimed in claim 2, wherein the source region comprises a second portion extending along the first direction, and the first portion is located between the second portion and the channel region.

8. The electronic device as claimed in claim 2, wherein one of the semiconductor structures has an inclined portion extending along the second direction, the inclined portion has a length (L) along the first direction, and the one of the semiconductor structures has a distance (X) between the source region and the drain region along an extension direction of the gate line, and the acute angle (0) satisfies the following relationship:
$$0 ° < θ \leq {tan}^{- 1} ( \frac{X}{L} ) .$$

9. The electronic device as claimed in claim 8, wherein the source region comprises a second portion extending along the first direction, and the first portion is located between the second portion and the channel region.

10. The electronic device as claimed in claim 8, wherein in the first direction, the length of the inclined portion is greater than or equal to a width of the gate line.

11. The electronic device as claimed in claim 8, wherein the channel region extends along the second direction.

12. The electronic device as claimed in claim 8, wherein the inclined portion comprises a part of the drain region.

13. The electronic device as claimed in claim 8, wherein the distance is greater than 0 μm and less than 10 μm.

14. The electronic device as claimed in claim 1, wherein the drain region comprises a first portion extending along the second direction.

15. The electronic device as claimed in claim 1, wherein the gate line is substantially perpendicular to the data line.

16. The electronic device as claimed in claim 1, wherein the source region is electrically connected to the data line through a hole overlapping the data line.

17. An electronic device, comprising:
a substrate;
a data line and a gate line disposed on the substrate, wherein the data line extends along a first direction; and
a thin film transistor disposed on the substrate and comprising a semiconductor structure, wherein the semiconductor structure comprises a channel region, a source region and a drain region, wherein the gate line overlaps the channel region, the channel region at least partially overlaps the data line, the source region is electrically connected to the data line, and the source region and the drain region are located on opposite sides of the gate line, wherein the drain region comprises a first portion extending along a second direction, and an acute angle is formed between the first direction and the second direction.

18. The electronic device as claimed in claim 17, wherein the thin film transistor comprises another semiconductor structure disposed adjacent to the semiconductor structure, wherein the another semiconductor structure comprises a channel region, a source region and a drain region, wherein the source region of the another semiconductor structure and the drain region of the another semiconductor structure are located on opposite sides of the gate line, wherein the drain region of the another semiconductor structure comprises a first portion extending along a third direction, and the third direction is different from the second direction.

19. The electronic device as claimed in claim 18, wherein the third direction is perpendicular to the second direction.

20. The electronic device as claimed in claim 17, further comprising another data line disposed parallel to the data line, and the drain region is equidistant from the data line and the another data line.
